(19) United States
(12) Patent Application Publication
(10) Pub. No.: US 2006/0038264 A1
(43) Pub. Date: Feb. 23, 2006

(54) Printed circuit board

(75) Inventor: Toshio Ishimoto, Takefu-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Takefu-city (JP)

(21) Appl. No.: 11/205,331

(22) Filed: Aug. 17, 2005

(30) Foreign Application Priority Data
Aug. 18, 2004 (JP) 2004-238690

(51) Int. Cl. H01L 23/495

(52) U.S. Cl. 257/668

(57) ABSTRACT

To provide a printed circuit board in which two wiring patterns having a width of 0.15 mm, which are to be passed through the area of the printed circuit board for mounting a 1608-size chip component, are formed by printing, thereby increasing the circuit packaging density, reducing the production cost and suppressing the yield reduction. In a range in which the distance between two lands 12 to which a surface-mount chip component is electrically connected (the distance between points 17a and 17b) allows formation of two wiring patterns having a line width of 0.25 mm (the distance is equal to or more than 1.25 mm), wiring patterns 15 and 16 having a line width of 0.25 mm are formed. In this way, parts of the wiring patterns having a line width of 0.15 mm (narrow parts 15a and 16a) are minimized, and thus, the reduction in production yield is suppressed.

The present application is based on and claims priority of Japanese patent application No. 2004-238690 filed on Aug. 18, 2004, the entire contents of which are hereby incorporated by reference.

### BACKGROUND OF THE INVENTION

1. Field of the Invention

The present invention relates to a printed circuit board on which surface-mount chip components are mounted. In particular, it relates to a printed circuit board on which a wiring pattern to extend under surface-mount chip components is formed by printing.

2. Description of the Related Art

To reduce the size and weight of electronic apparatus, more electronic components for printed circuit boards are becoming manufactured as chips, and the packaging densities of such chip components on printed circuit boards are becoming higher. In order to increase the packaging density of electronic circuit on a printed circuit board, the layout of the wiring pattern that interconnects the electronic components is important, and the way of layout and the way of formation of the wiring pattern are investigated in various ways for increasing the packaging density of the circuit.

Techniques for layout or formation of wiring patterns for increasing the circuit packaging density according to the prior art are disclosed in Japanese Patent Laid-Open Publication No. 3-233991, Japanese Patent Laid-Open Publication No. 5-57863, Japanese Patent Laid-Open Publication No. 9-18097 and Japanese Patent Laid-Open Publication No. 11-340590, for example.

### SUMMARY OF THE INVENTION

As a method for enhancing the circuit packaging density as described above, it is common practice to pass a wiring pattern under a surface-mount chip component. Standard sizes of surface-mount chip components include a 2125-size (a size of 2 mm by 1.25 mm) and a 1608-size (a size of 1.6 mm by 0.8 mm), and the longitudinal dimension of a 1608-size chip component is 1.6 mm. However, when mounting the chip component on a printed circuit boar, soldering of terminal parts has to be allowed for, and thus, the width of the space through which the wiring pattern can be passed under the mounted 1608-size chip component (that is, the distance between two lands to which the terminals of the chip component are electrically connected) is actually about 1.0 mm. In order to pass two wiring patterns through such a space having a width of 1.0 mm, it is desirable that the line width of the wiring patterns is 0.15 mm, considering the facts that the distance between each wiring pattern and the land opposing to the wiring pattern is desirably 0.25 mm or more (because the forming error (maximum printing deviation) of the openings for the lands in the applied solder resist is about 0.15 mm) and that the distance between the wiring patterns is desirably 0.2 mm or more (because the adjacent wiring patterns may come into contact with each other and the solder resist may be difficult to apply if the distance is equal to or smaller than 0.2 mm).

In the case where wiring patterns are formed by photography (photo etching), a wiring pattern having a width of 0.15 mm can be formed without any problem, and thus, two wiring patterns can be passed through the space having a width of 1.0 mm. However, the photo etching has a problem that it requires high production cost and long production period. On the other hand, in the case where wiring patterns are formed by printing (screen printing), although the printing technique has recently become able to produce a wiring pattern having a width of 0.15 mm, there remains a problem that the production yield decreases (and, as a result, the cost increases) if a large number of wiring patterns having a width of 0.15 mm are formed.

In view of such circumstances, an object of the present invention is to provide a printed circuit board in which two wiring patterns having a width of 0.15 mm, which are to be passed through the area of the printed circuit board for mounting a 1608-size chip component, are formed by printing, thereby increasing the circuit packaging density, reducing the production cost and suppressing the yield reduction.

A printed circuit board according to a first implementation is a printed circuit board on which a 1608-size surface-mount chip component is to be mounted, comprising: two wiring patterns formed by printing between two lands to which terminals of the 1608-size surface-mount chip component are electrically connected.

According to this implementation, two wiring patterns are formed by printing under the chip component mounted.

A printed circuit board according to a second implementation is the printed circuit board according to the first implementation, in which the two wiring patterns have a line width of 0.15 mm, the distance between the two wiring patterns is 0.2 mm or more, and the distance between each wiring pattern and the land opposing the wiring pattern is 0.25 mm or more.

A printed circuit board according to a third implementation is the printed circuit board according to the first or second implementation, in which the two wiring patterns each have a wide part that extends within a range where the distance between opposing two intersections of the intersections of a straight line parallel to the longitudinal direction of the 1608-size surface-mount chip and the two lands is 1.1 mm or more.

The expression “the distance between opposing two intersections of the intersections of a straight line parallel to the longitudinal direction of the 1608-size surface-mount chip and the two lands” means the distance between the two lands at a particular y coordinate in a coordinate system whose x axis extends in the longitudinal direction of the chip component and whose y axis extends in the lateral direction of the chip component, or the distance between the intersection of a line that is parallel to the longitudinal direction of the chip component (that is, parallel to the x axis) and is moving in the lateral direction (that is, along the y axis) and one of the lands and the intersection of the same line and the other land (thus, for example, if rectangular lands are formed in parallel to each other, “the distance between the opposing two intersections of the line parallel to the longitudinal direction of the chip component and the two lands is constant within an area between the lands or infinite outside the area between the lands”). Therefore, according to this implementation, the wiring patterns extending under the chip component each have a wide part within a range where the distance between the two lands is 1.1 mm or more. The value of “1.1 mm” is a total of the sum of the widths of the two wiring patterns each having a width of 0.2 mm (0.2 mm×2=0.4 mm), which is greater than 0.15 mm, the distance of 0.2 mm between the wiring patterns, and the sum of the distances between the wiring patterns and their respective opposing lands (0.25 mm×2=0.5 mm) and represents the width that allows formation of the wiring patterns having a line width of 0.2 mm.

A printed circuit board according to a fourth implementation is the printed circuit board according to the third implementation, in which the wide part of the wiring pattern has a line width of 0.2 mm.

A printed circuit board according to a fifth implementation is the printed circuit board according to any one of the first to fourth implementations, in which the two wiring patterns each have a wide part that extends within a range where the distance between opposing two intersections of the intersections of a straight line parallel to the longitudinal direction of the 1608-size surface-mount chip and the two lands is 1.25 mm or more.

The value of “1.25 mm” is a total of the sum of the widths of the two wiring patterns each having a width of 0.25 mm (0.25 mm×2=0.5 mm), which is greater than 0.15 mm and 0.2 mm, the distance of 0.25 mm between the wiring patterns, and the sum of the distances between the wiring patterns and their respective opposing lands (0.25 mm×2=0.5 mm) and represents the width that allows formation of the two wiring patterns having a line width of 0.25 mm with the distance between the wiring patterns being kept at 0.25 mm.

A printed circuit board according to a sixth implementation is the printed circuit board according to the fifth implementation, in which the wide part of the wiring pattern has a line width of 0.25 mm.

A printed circuit board according to a seventh implementation is a printed circuit board on which a surface-mount chip component is to be mounted, comprising: wiring patterns having a line width of 0.15 mm that are formed by printing between two lands to which terminals of the surface-mount chip component are electrically connected, in which the distance between the wiring patterns having a line width of 0.15 mm is 0.2 mm or more, the distance between each wiring pattern and the land opposing the wiring pattern is 0.25 mm or more, and each of the wiring patterns having a line width of 0.15 mm has a wide part that extends at least outside the area of the printed circuit board directly under the surface-mount chip component.

According to this implementation, the wiring patterns having a line width of 0.15 mm are formed by printing under the surface-mount chip component with the distance between the wiring patterns being kept at 0.2 mm or more and the distances between the wiring patterns and their respective opposing lands being kept at 0.25 mm or more and each have a part that has a line width greater than 0.15 mm and extends at least outside the area of the printed circuit board directly under the surface-mount chip component. Here, the expression “the distance between the wiring patterns being kept at 0.2 mm or more” means that, if a plurality of wiring patterns are formed, the distance therebetween is kept at 0.2 mm or more, and therefore, the present invention is not limited to the case of a plurality of wiring patterns, and according to the present invention, only one wiring pattern may be formed.

### ADVANTAGES OF THE PRESENT INVENTION

According to the first implementation, a printed circuit board on which a 1608-size surface-mount chip component is to be mounted comprises: two wiring patterns formed by printing between two lands to which terminals of the 1608-size surface-mount chip component are electrically connected. In this case, since two wiring patterns extends under the 1608-type chip component, the circuit packaging density increases. In addition, since the wiring patterns are formed by printing, the production cost and period can be reduced compared to the case of using a photography technique.

According to the third implementation, in the printed circuit board according to the first or second implementation, the two wiring patterns each have a wide part that extends within a range where the distance between opposing two intersections of the intersections of a straight line parallel to the longitudinal direction of the 1608-size surface-mount chip and the two lands is 1.1 mm or more. In this case, since the pattern size (line width) is increased within the range in which a clearance of 1.1 mm is assured between the lands and the wiring patterns having a line width of 0.2 mm can be formed, the range of formation of the narrow parts of the wiring patterns having a line width of 0.15 mm, which causes reduction in yield when the wiring patterns are formed by printing, can be minimized. Thus, the production cost and period can be advantageously reduced by using the printing technique, while suppressing the reduction in yield due to the use of the printing technique.

According to the fifth implementation, in the printed circuit board according to any one of the first to fourth implementations, the two wiring patterns each have a wide part that extends within a range where the distance between opposing two intersections of the intersections of a straight line parallel to the longitudinal direction of the 1608-size surface-mount chip and the two lands is 1.25 mm or more. In this case, since the pattern size (line width) is increased within the range in which a clearance of 1.25 mm is assured between the lands and the wiring patterns having a line width of 0.25 mm can be formed, the reduction in production yield can be further suppressed.

According to the seventh implementation, a printed circuit board on which a surface-mount chip component is to be mounted comprises wiring patterns having a line width of 0.15 mm that are formed by printing between two lands to which terminals of the surface-mount chip component are electrically connected, the distance between the wiring patterns having a line width of 0.15 mm is 0.2 mm or more, the distance between each wiring pattern and the land opposing the wiring pattern is 0.25 mm or more, and each of the wiring patterns having a line width of 0.15 mm has a wide part that extends at least outside the area of the printed circuit board directly under the surface-mount chip component. In this case, since the wiring patterns having a line width of 0.15 mm are formed by printing under the surface-mount chip component, the print circuit board whose circuit packaging density is improved can be produced at low cost in a short production period. In addition, since the part of the wiring pattern having the line width of 0.15 mm is minimized, the reduction in production yield can be suppressed.

### BRIEF DESCRIPTION OF THE DRAWINGS

FIG. 1a is a perspective view of apart of a printed circuit board in which wiring patterns according to the present invention are formed;

FIG. 1b is a cross-sectional view taken along the line A-A in FIG. 1a;

FIG. 2 is a top view of the part of the printed circuit board in which the wiring patterns according to the present invention are formed;

FIG. 3 shows the same as FIG. 2 except that a chip component is removed;

FIG. 4 is a top view of a part of another printed circuit board according to the present invention in which wiring patterns are formed;

FIG. 5 is a top view of a part of another printed circuit board according to the present invention in which wiring patterns are formed; and

FIG. 6 shows two wiring patterns having a line width of 0.25 mm extending under a 1608-type chip.

### DETAILED DESCRIPTION OF THE PREFERRED EMBODIMENTS

In the following, a specific embodiment of the present invention will be described with reference to the drawings. However, it is to be noted that the embodiment described below is intended only for illustration and is not intended to limit the scope of the present invention.

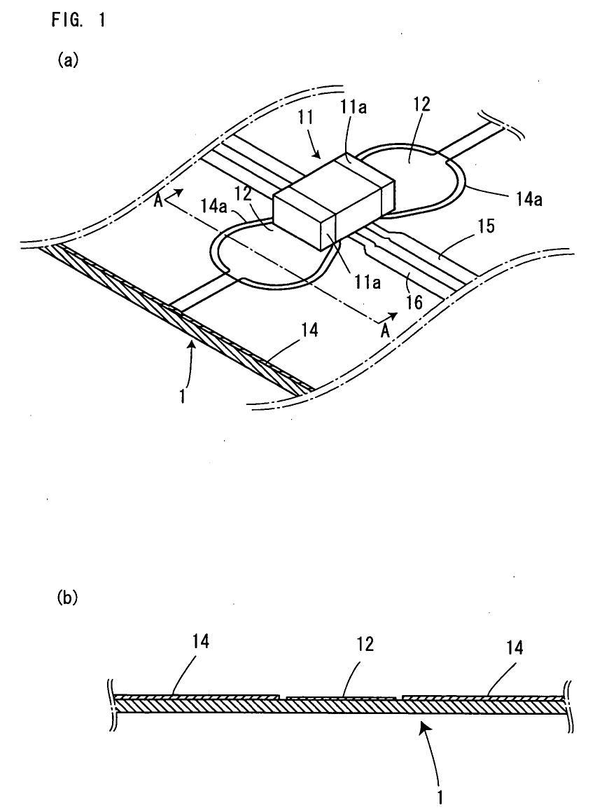

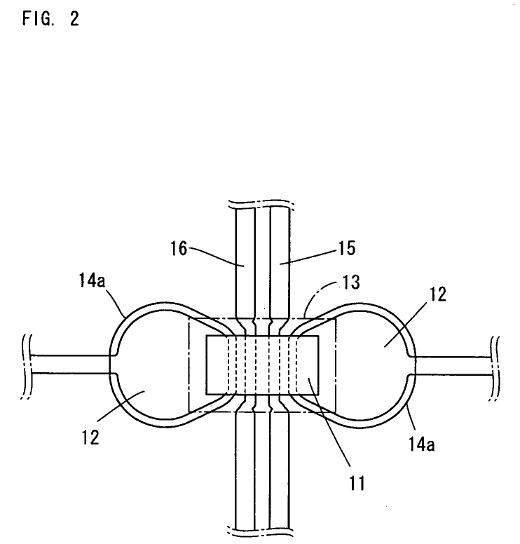

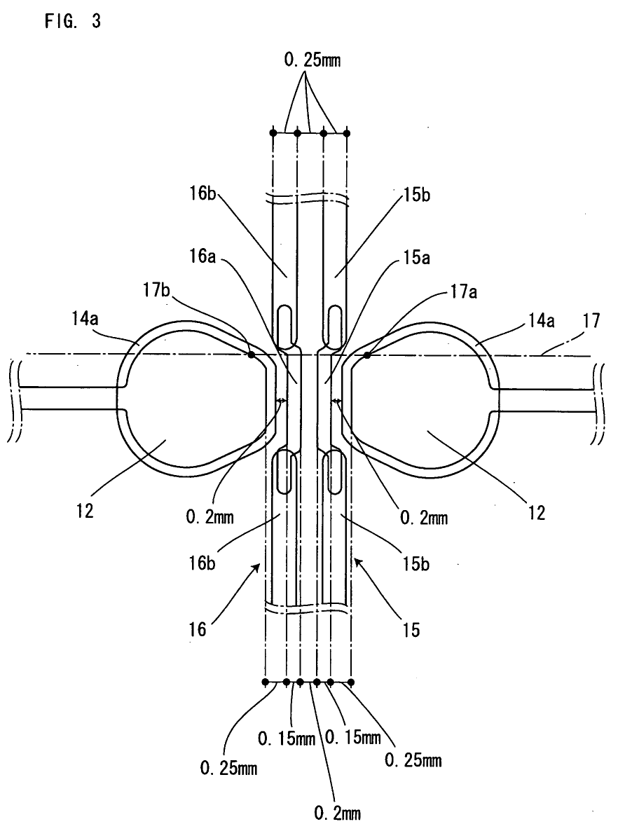

FIG. 1 contains enlarged views of a part of a printed circuit board according to this embodiment of the present invention in which wiring patterns according to the present invention is formed: FIG. 1a is a perspective view thereof; and FIG. 1b is a cross-sectional view thereof taken along the line A-A. FIG. 2 is a top view of the same part, and FIG. 3 is the same as FIG. 2 except that a chip component is removed.

As shown in FIGS. 1 and 2, on a printed circuit board 1 according to this embodiment, lands 12 made of a copper foil are formed, and a surface-mount chip component 11 of a size of 1608 (that is, a size of 1.6 mm by 0.8 mm) (referred to simply as 1608-type chip, hereinafter) is mounted on the printed circuit board 1 by soldering terminals 11a to the lands 12. To prevent excessive solder from coming into contact with the other parts during soldering of the terminals 11a to the lands 12, a solder resist 14 is applied to the area other than openings 14a. As shown in FIG. 2, the lands 12 according to this embodiment are designed so that a surface-mount chip component 13 of a size of 2125 (that is, a size of 2 mm by 1.25 mm) (referred to simply as 2125-type chip, hereinafter) can be mounted on the printed circuit board 1.

As shown in FIG. 3, wiring patterns 15 and 16 are disposed (between the lands 12) so as to extend under the 1608-type chip 11 to be mounted. The wiring patterns 15 and 16 have narrow parts 15a and 16a having a line width of 0.15 mm and extending between the lands 12, respectively, and the narrow parts 15a and 16a are spaced apart from each other by 0.2 mm and spaced apart from their respective opposing lands 12 by 0.25 mm. Wide parts 15b and 16b of the wiring patterns 15 and 16 have a line width of 0.25 mm and are spaced apart from each other by 0.25 mm. The wiring patterns on the printed circuit board 1 according to this embodiment are formed by etching a copper foil on an insulating plate into a predetermined pattern, and the resist pattern for the etching is formed by printing (screen printing). FIG. 3 shows the narrow parts 15a and 16a and the wide parts 15b and 16b as being stacked one on another at the connections thereof. However, this is a CAD view of the wiring patterns under design, in which the 0.15-mm-wide pattern and the 0.25-mm-wide pattern are drawn separately. FIG. 3 is drawn in this way solely to help understanding of the present invention, and the actual wiring patterns are as shown in FIGS. 1 and 2.

The forming error (the maximum printing deviation) of the solder resist 14 (openings 14a) is about 0.15 mm, and thus, if the lands 12 (or the resist openings 14a) are too close to the wiring patterns 15a and 16a, the wiring patterns 15a and 16a may overlap with the openings 14a (if the wiring pattern 15 or 16 overlaps with the opening 14a, the solder resist 14 is not applied to the overlapping part of the wiring pattern, and the solder adheres to the wiring pattern to cause accidental short-circuit). The distance of 0.25 mm between the narrow parts 15a and 16b and their respective opposing lands 12 is intended to avoid this possibility. In this embodiment, the openings 14a are spaced apart from the respective lands 12 by 0.05 mm, and thus, setting the distance of the narrow parts 15a and 16a from their respective opposing lands 12 at 0.25 mm results in a distance of 0.2 mm between the wiring patterns 15a and 16a and their respective openings 14a, and thus, a distance not less than the forming error of 0.15 mm is assured therebetween. The distance of 0.2 mm between the narrow parts 15a and 16a is intended to avoid the possibilities, which arise if the distance between the narrow parts 15a and 16a is less than 0.2 mm, that the adjacent wiring patterns may come into contact with each other, and that the solder resist 14 may be difficult to appropriately apply.

The line width of the wide parts 15b and 16b of 0.25 mm and the distance between the wiring patterns of 0.25 mm are designed to assure that the wiring patterns be formed by screen printing with high yield (that is, with few defectives). For the same reason as described above, the wide parts 15b and 16b have to be spaced apart from the lands 12 by 0.25 mm or more, and thus, a “clearance” of 1.25 mm (=0.25*5) is needed to form the wide parts (having a width of 0.25 mm) 15b and 16b. Thus, the wiring patterns 15 and 16 change from the narrow parts 15a and 16a to the wide parts 15b and 16b, respectively, in a part where the distance between inner two intersections (points 17a and 17b) of the intersections of a straight line 17 parallel to the longitudinal direction of the 1608-type chip 11 and the two lands 12 is 1.25 mm or more.

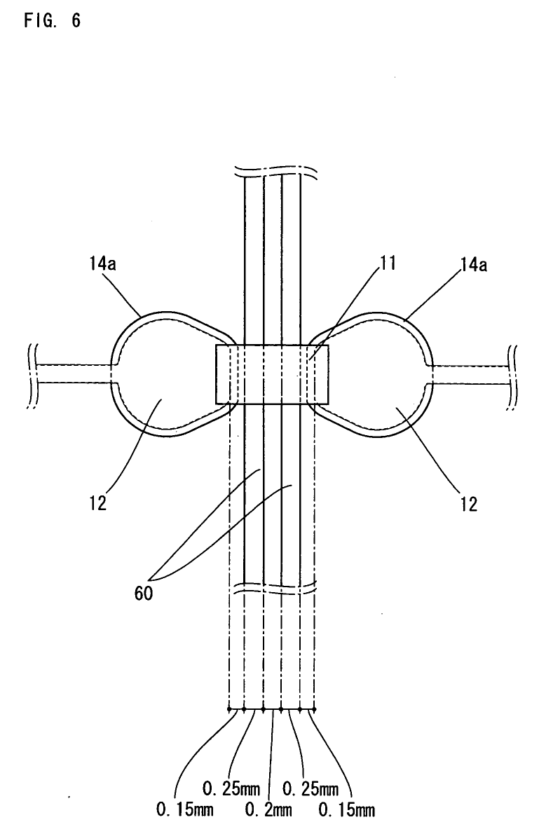

FIG. 6 shows a case where two wiring patterns 60 having a line width of 0.25 mm extend under the 1608-type chip 11. The length of the 1608-type chip 11 is 1.6 mm. However, soldering of the terminals 11a for mounting the chip on the printed circuit board has to be allowed for, so that the width of the space in which the wiring patterns can pass through under the mounted 1608-type chip 11 (that is, the distance between the lands 12) is about 1.0 mm. As described above, since the distance between the wiring patterns has to be 0.2 mm or more, the distance between each wiring pattern 60 and the opposing land 12 cannot be greater than 0.15 mm, so that the distance between the wiring pattern 60 and the opposing solder resist opening 14a is equal to or smaller than 0.15 mm. Thus, as described above, the forming error of the solder resist cannot be accommodated. Therefore, considering that two wiring patterns are passed under the 1608-type chip 11, it is desirable that the line width of the wiring patterns is 0.15 mm. However, if wiring patterns having a line width of 0.15 mm are formed by printing (screen printing), the fraction defective exponentially increases with the amount of the wiring patterns.

In the printed circuit board 1 according to this embodiment, the wiring patterns have a line width of 0.15 mm only in a required minimum part thereof, so that the reduction in yield can be minimized even if the wiring patterns are formed by printing (screen printing). In addition, since printing is used for forming the wiring patterns, the production cost and period can be reduced.

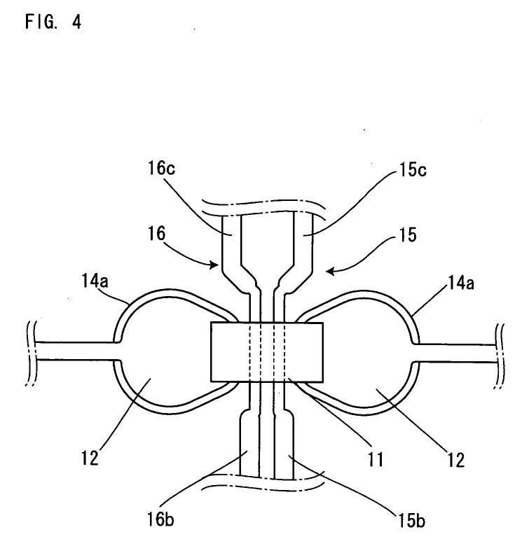

According to this embodiment, the line width of the wide parts 15b and 16b is 0.25 mm, and the distance between the wide parts is 0.25 mm. However, the present invention is not limited to these specific values, the wide parts may have any dimensions as far as they can be formed by printing with high yield. For example, the line width of the wide parts may be 0.2 mm, and the distance therebetween may be 0.2 mm. If layout of the wiring patterns permits, the distance between the wide parts 15c and 16c can be widened as shown in FIG. 4.

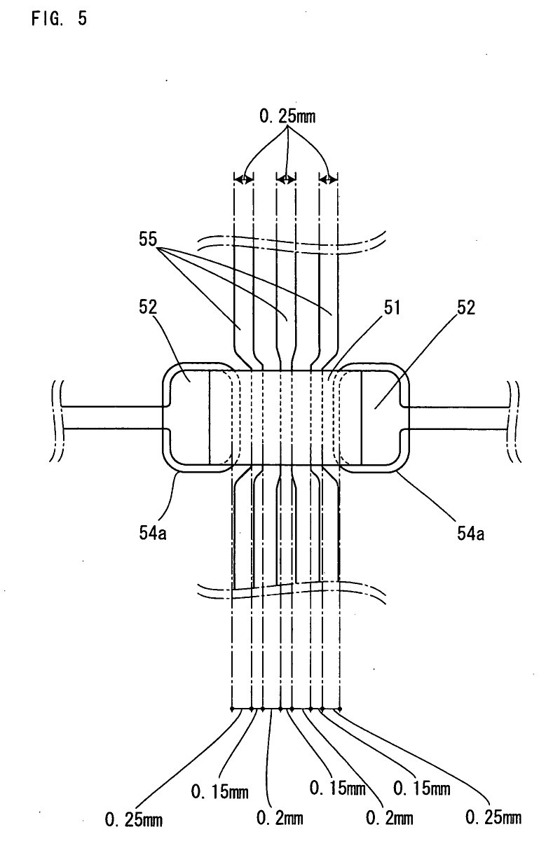

In addition, according to this embodiment described above, the 1608-type chip is used as a mount-surface chip component. However, the present invention is not limited thereto. For example, as shown in FIG. 5, three wiring patterns 55 each having a narrow part having a width of 0.15 mm and a wide part having a width of 0.25 mm may be formed by printing under a surface-mount chip component 51 of a size of 2125 (a size of 2 mm by 1.25 mm) with the narrow parts being spaced apart from each other by 0.2 mm, the outer wiring patterns 55 being spaced apart from their respective opposing lands 52 by 0.25 mm, and the wide parts extending at least outside of the area of the printed circuit board directly under the surface-mount chip component 51 (that is, the area having a width allowing formation of the wiring patterns having a width of 0.25 mm).

1. A printed circuit board on which a 1608-size surface-mount chip component is to be mounted, comprising: two wiring patterns formed by printing between two lands to which terminals of the 1608-size surface-mount chip component are electrically connected.

2. The printed circuit board according to claim 1, wherein the two wiring patterns have a line width of 0.15 mm, the distance between the two wiring patterns is 0.2 mm or more, and the distance between each wiring pattern and the land opposing the wiring pattern is 0.25 mm or more.

3. The printed circuit board according to claim 1 or 2, wherein the two wiring patterns each have a wide part that extends within a range where the distance between opposing two intersections of the intersections of a straight line parallel to the longitudinal direction of the 1608-size surface-mount chip and the two lands is 1.1 mm or more.

4. The printed circuit board according to claim 3, wherein the wide part of the wiring pattern has a line width of 0.2 mm.

5. The printed circuit board according to claim 1 or 2, wherein the two wiring patterns each have a wide part that extends within a range where the distance between opposing two intersections of the intersections of a straight line parallel to the longitudinal direction of the 1608-size surface-mount chip and the two lands is 1.25 mm or more.

6. The printed circuit board according to claim 5, wherein the wide part of the wiring pattern has a line width of 0.25 mm.

7. A printed circuit board on which a surface-mount chip component is to be mounted, comprising: wiring patterns having a line width of 0.15 mm that are formed by printing between two lands to which terminals of the surface-mount chip component are electrically connected, wherein the distance between the wiring patterns having a line width of 0.15 mm is 0.2 mm or more, the distance between each wiring pattern and the land opposing the wiring pattern is 0.25 mm or more, and each of the wiring patterns having a line width of 0.15 mm has a wide part that extends at least outside the area of the printed circuit board directly under the surface-mount chip component.
